(19) United States
(12) Patent Application Publication
(10) Pub. No.: US 2010/0044670 A1
(43) Pub. Date: Feb. 25, 2010

(54) Semiconductor device structures having single-crystalline switching device on conducting lines and methods thereof

(76) Inventor: Peiching Ling, San Jose, CA (US)

Correspondence Address: PEICHING LING, 1135 E ARQUES AVE, SUNNYVALE, CA, 94085, US

(21) Appl. No.: 12/381,392

(22) Filed: Mar. 10, 2009

Related U.S. Application Data
(60) Provisional application No. 61/089,980, filed on Aug. 19, 2008.

(51) Int. Cl. H01L 45/00; H01L 21/22

(52) U.S. Cl. 257/4; 438/478; 257/E45.002; 438/762; 257/E21.135

(57) ABSTRACT

A memory device includes a composite dielectric layer overlying a substrate. The composite dielectric layer includes a first dielectric layer, a bonding interface, and a second dielectric layer. The first and the second dielectric layers are bonded together at the bonding interface. A first plurality of conductive lines overlies the combined dielectric layer. One or more semiconductor switching devices formed in a single-crystalline semiconductor layer overlie and are coupled with one of the first plurality of conductive lines. The memory device also has one or more two-terminal memory elements, each of which overlies and is coupled to a corresponding one of the single-crystalline switching device. A second plurality of conductive lines overlies the memory elements. In the memory device, each of the memory elements is coupled to one of the first plurality of conductive lines and one of the second plurality of conductive lines.

### CROSS-REFERENCES TO RELATED APPLICATIONS

This application claims priority to U.S. Provisional Application No. 61/089,980 filed Mar. 18, 2008 entitled “STRUCTURE AND METHODS TO MANUFACTURE CONDUCTING LINES, FOR VERTICAL DIODES OR TRANSISTORS” by inventor Peiching Ling, commonly owned and incorporated by reference herein for all purposes.

### FIELD OF THE INVENTION

The invention relates generally to the structure and fabrication process of semiconductor devices. More particularly, some embodiments of this invention relate to the structure and fabrication process of semiconductor devices having single crystalline semiconductor switching devices formed directly on metal lines.

### BACKGROUND OF THE INVENTION

As the overall dimensions of semiconductor devices are miniaturized and made ever smaller, the formation of reliable and high conductivity electrodes and electrical lines as wordlines and bitlines of memory arrays become a limiting factor in the fabrication process for memory devices, such as but not limited to phase-change memory (PCM) device, magnetic random access memory (MRAM) device, where the operation of such devices require high currents. For both PCM memory devices and MRAM, it is commonly to use either diodes or transistors to select specific memory cells for read or write operations. Specifically, in order to accurately read and write the data stored in the phase-change memory cells, it is desirable for the diodes and transistors used to select the memory cells for read or write to have high ratios of Ion/Ioff, where Ion is the current of a diode or transistor in the turn-on state, and Ioff is the current of a diode or transistor in the turn-off state. Furthermore, it is desirable that the wordlines and bitlines and the diodes or the transistors devices in between can be formed with vertical structures to minimize the required areas for increasing the memory cell density. However, the high ratios of ON-OFF currents cannot be conveniently achieved. Specifically, a high ON-OFF current ratio is achievable when a vertical diodes or transistors are formed with single crystal silicon instead of non-single crystal silicon such as amorphous silicon, re-crystallized silicon or polysilicon.

In the meantime, each of these diodes or transistors must be connected to metal wordlines and bitlines which connect each individual cell to the wordline decoders and bitline sensing circuitry and decoders. For the purpose of high performance, either low resistance-capacitance (RC) delay, or low resistance-current (IR) voltage drop, the wordlines and bitlines are highly preferred to be formed by highly conductive materials, such as copper (Cu), aluminum (Al), tungsten (W), refractive metal silicides. In many prior art processes, heavily doped silicon or polysilicon are also commonly used. However, heavily doped silicon or polysilicon have higher resistivity than metal, therefore, it is highly desirable to have both wordlines and bitlines of memory arrays to be made of metal materials.

In prior arts, metal lines can be easily fabricated on top of single-crystal silicon; however, in prior arts, metal lines underneath a single crystal silicon layer cannot be conveniently formed. In prior arts either the wordlines or the bitlines have to be manufactured with heavily doped silicon or polysilicon to serve as conductive lines instead of metal lines. Examples of such prior art configurations and manufacturing methods have been disclosed by Oh et. al in “Full Integration of Highly Manufacturable 512 Mb PRAM based on 90 nm Technology (IEDM 06-49 2006IEEE) and by Bedeschi et. al in “An 8 Mb Demonstrator for High Density 1.8 V Phase-change Memories (2004 Symposium on VLSI Circuit Design of Technical Papers 2004IEEE). As illustrated by the two prior art examples, the goals of a having a single crystal silicon layer to fabricate high ON-OFF current ratio diodes or transistors, and having a high conductivity layer for the conductive lines underneath the diodes or transistors cannot be achieved by either types of the conventional technologies.

The demand for an improved configuration and process of manufacturing reliable electrodes and low resistivity electrical conducting lines to function as bitlines and/or wordlines while keeping active diodes or transistors with high Ion/Ioff ratio for memory devices is ever increased. Both the PCM and MRAM devices are attracting increasing interests as candidates for next generation non-volatile memories. The PCM cells have distinct advantages because the PCM memories can be operated at low voltage with fast operation. Additionally, the PCM memories have extended cycling endurance highly desired for Solid State Disk (SSD) applications and promising scaling potential. However, the conventional PCM configurations and manufacturing processes are still confronted with the technical difficulties that a goal of achieving high ratio of Iₒₙ/I_{off} cannot conveniently achieved in prior arts due to the difficulties of forming the metal conducting lines underneath a single crystal silicon layers to function either as wordlines or bitlines.

FIGS. 1 and 2 are cross sectional views of a vertical PCM cells implemented with array of PNP bipolar transistors and/or diodes with respective contacts on both sides. The diodes or transistor can be formed either on single crystal silicon, amorphous silicon, re-crystallized silicon or polysilicon. It is desirable to form the diodes or the transistors in a single crystal silicon layer to achieve high ratio of Iₒₙ/I_{off}. However, with a single crystal silicon layer, it is inconvenient to form the metal conducting lines underneath the single crystal silicon layer to function as either as the bitlines or wordlines. Therefore, due to this limitation, a high performance PCM device with high Iₒₙ/I_{off} ratio and low resistivity operable with long reliable cycling time having high cell density with reduced pitch size cannot be conveniently achieved.

U.S. Pat. Nos. 5,374,564 and 6,323,110 disclose manufacturing processes to form devices on a silicon on insulator (SOI) semiconductor wafers. However, the focus of the disclosures are directed to the formation of devices on the thin layers above the insulator layer such that the SOI devices can be insulated from interferences from signals that may be formed underneath the insulation layer. Even though the disclosures made in these Patents would not directly relevant to the disclosures made in this Patent Application, however, since there are similarities in some of the manufacturing processes, the disclosures made in these Patents including the wafer structures and manufacturing methods are hereby incorporated by references in this Patent Application.

For all the above reasons, there still is need for those of ordinary skill in the art to provide a new and improved method such that the above discussed difficulties and limitations can be overcome.

### SUMMARY OF THE PRESENT INVENTION

According to some embodiments of the invention, a memory device includes a composite dielectric layer overlying a substrate. The composite dielectric layer has a first dielectric layer, a bonding interface, and a second dielectric layer, and the first and the second dielectric layers are bonded together at the bonding interface. The memory device also has a first plurality of conductive lines overlying the combined dielectric layer. One or more semiconductor switching devices are formed in a single-crystalline semiconductor layer overlying and coupled with one of the first plurality of conductive lines. The memory device has one or more two-terminal memory elements, each of which overlies and is being coupled to a corresponding one of the single-crystalline switching devices. A second plurality of conductive lines overlies the memory elements. Each of the memory elements is coupled to one of the first plurality of conductive lines and one of the second plurality of conductive lines. In a specific embodiment, each of the two-terminal memory elements comprises a phase change memory (PCM) material.

According to another embodiment of the present invention, a method for forming a memory device includes forming a single-crystalline semiconductor layer overlying and in direct contact with a metal layer, and forming two or more doped layers in the single-crystalline semiconductor layer. The method includes forming a layer of memory material overlying the single-crystalline semiconductor layer, wherein the memory material's conductivity property can be set by an applied voltage and the memory material retains the conductivity property after the applied voltage is removed. The method also includes forming a layer of conductive material overlying the layer of memory material.

According to some embodiments of the present invention, a semiconductor substrate has a top surface region including a single crystal silicon layer with a predefined thickness disposed immediately above a metal layer on top of a combined dielectric layer, which can have a first dielectric layer, a bonding interface; and a second dielectric layer. The first and the second dielectric layers are bonded together at the bonding interface. In a specific embodiment, the single crystal silicon layer further includes one or more diodes.

Some embodiments of the present invention provide improved structures and fabrication process for conveniently forming metal layers for patterning into wordlines and bitlines both above and underneath a single crystal silicon layer to achieve high Ion-Ioff ratios diodes or transistors such that the above discussed difficulties and limitations may be resolved.

Specifically, it is an aspect of the present invention to provide a base supporting structure to manufacture a memory device thereon with conductive layer both above and underneath a single crystal silicon layer which enables diodes or transistors with high on-off current ratios. A conductive layer is formed either with metals such as tungsten, Cu, TiN, TiW, Ni, . . . etc. deposition or as doped polysilicon layer with convenient manufacturing processes. Furthermore, a single crystal silicon layer is provided to form transistors or diodes right on top of the conductive layer such that high on-off current ratio can be achieved.

It is also an aspect of the present invention to provide a base supporting structure to manufacture a memory device thereon with conductive layer underneath a single crystal silicon layer. The single crystal layer can be further processed to manufacture memory peripheral circuits The conductive layer may be formed with Cu, W, TiN, TiW, Ni, refractory metal silicides such as Ti-Silicide, W-Silicide, Ni-Silicide, Co-Silicide, Polysilicon, and conductive layers typically used in semiconductor industries for connecting circuits manufactured as the integrated circuits (IC).

Another aspect of this invention is to provide improved manufacturing processes including multiple steps before the bonding of the two wafers used to form the final structure. The processes include gate oxide formation, polysilicon deposition, polysilicon etch, polysilicon sidewall protection, source and drain ion implantations, and anneal operations on one wafer. The processes may further include the formation and patterning of metal contact to the peripheral circuits and transistors necessary to support the memory operation, then cover top surface with insulation layer followed with a chemical mechanical planarization process (CMP) before the bonding operation to form the final structure. The second wafer has patterned or un-patterned metal layer and oxide on the top. Such manufacturing processes thus provide greater flexibilities of controlling and managing the manufacturing processes.

Another aspect of this invention is to provide improved manufacturing processes that may further include a bonding wafers and an etch process on a SOI (silicon on insulater) wafer with the oxide layer functioning as an etch stop. The memory cell and the peripheral circuits can be formed on the top silicon layer of the SOI wafer except the wordlines or bitlines. Then the wafer can be covered with a silicon oxide layer followed with a CMP process before the bonding to a second wafer or a glass wafer. The second wafer has a silicon oxide layer on the top, the first SOI wafer is then bonded to the second wafer, followed by etching the bulk of SOI with the oxide layer functioning as an etch stop. The low resistivity wordlines or bitlines can then be formed on top of the memory array. In the same process steps, the wordlines or bitlines make electrical contact to the periphery transistors and circuits.

Another aspect of this invention is to provide improved manufacturing processes that may further include an etch partial of the top silicon layer and oxide layer of SOI wafer, exposing the bulk silicon. The peripheral circuits are then formed on the exposed bulk silicon area, the memory cell may be formed on the rest of the top silicon layer of the SOI wafer except the worldliness or bitlines and then cover the whole substrate with an oxide layer followed by a CMP process before bonding to a second wafer or glass substrate. The second wafer has an oxide layer on the top. The first wafer is then bonded to the second wafer, followed by a masked etch to etch away the bulk of SOI wafer except for the periphery area where active transistors and circuits are intact. The low resistivity wordlines or bitlines can then be formed on top of the memory array. In the same process steps, the wordlines or bitlines make electrical contact to the periphery transistors and circuits.

These and other objects and advantages of the present invention will no doubt become obvious to those of ordinary skill in the art after having read the following detailed description of the preferred embodiment which is illustrated in the various drawing figures.

### BRIEF DESCRIPTION OF THE DRAWINGS

FIGS. 1 and 2 are cross-sectional views of prior art vertical phase change memory (PCM) cell structures with vertical BJT in FIG. 1 and diodes in FIG. 2.

FIGS. 3 to 7 are a series of cross sectional views illustrating the fabrication steps for providing a base structure with single crystal layer on top of low resistivity conducting layer to form memory cells or other electric circuit thereon.

FIGS. 8 to 14 are a series of cross sectional views illustrating the fabrication steps for providing another base structure with single crystal layer on top of low resistivity conducting layer to form memory cells or other electric circuit thereon.

FIGS. 15 to 20 are a series of cross sectional views illustrating the fabrication steps for providing another base structure with single crystal layer on top of low resistivity conducting layer to form memory cells or other electric circuit thereon.

FIGS. 21-24 are respectively a top views and cross sectional views of a based structure and a method for forming such structure for supporting and manufacturing PCM memory cells thereon.

FIGS. 25 to 28 show similar structures as illustrated in FIGS. 21 to 24 except that the doping polarities of the layers are reversed.

FIGS. 29 to 40 are a series of cross sectional views for showing processing steps to form the based-structures for the PCM memory cells and the peripheral device before, during and after the base structure is manufactured.

FIGS. 41 and 42 are cross sectional views for illustrating the PCM cells and the peripheral circuit supported on a silicon substrate according to the manufacturing processes as disclosed in FIGS. 29 to 40.

FIGS. 43 and 44 are cross sectional views for illustrating a phase-change memory structure and a magnetic random access memory (MRAM) supported on the base structures manufactured by applying the processes disclosed in this invention.

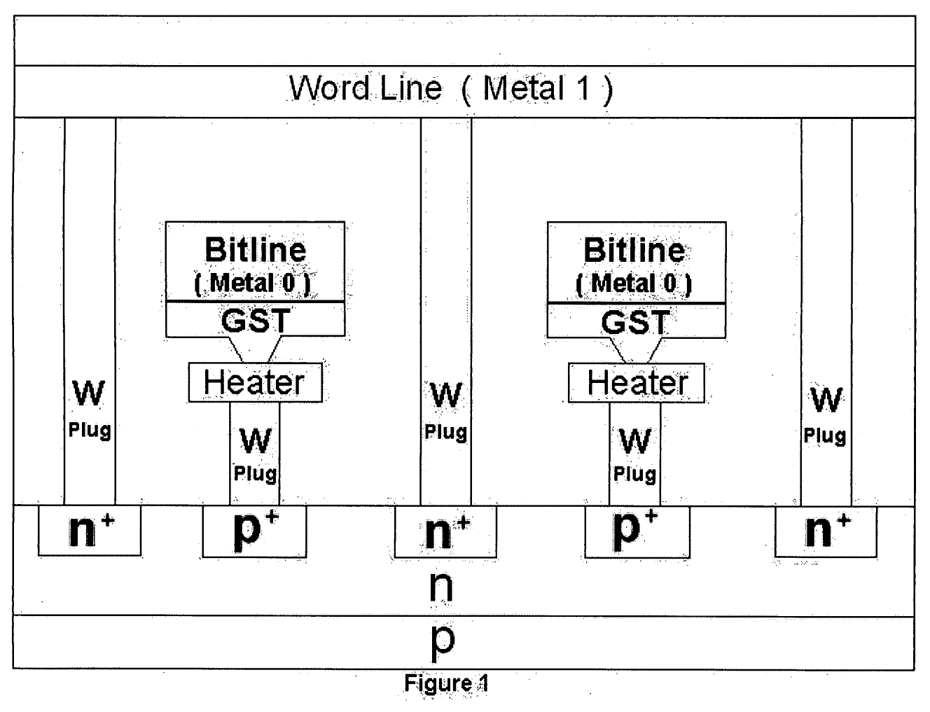

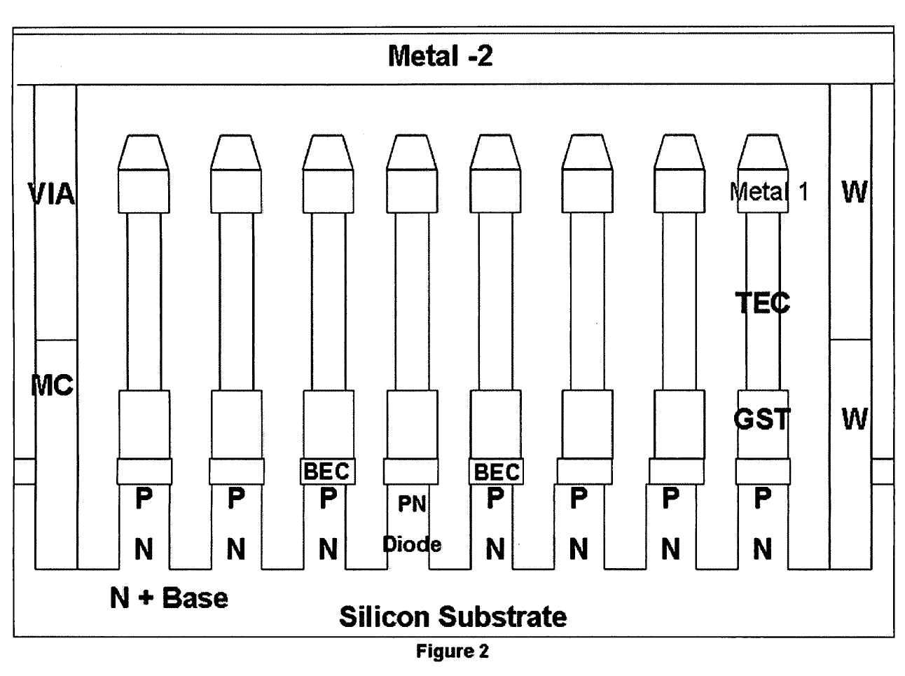

### DETAILED DESCRIPTION OF THE PREFERRED EMBODIMENT

For the purpose of this description, memory arrays are referred to as arrays of memory cells, that is, the elements or cells functioning as data storing memory; the terms “wafer”, “substrate”, “semiconductor wafer”, “semiconductor substrate” are often used interchangeably in the microelectronics field. As used herein, a “metal line” means a conductive line structure including metallic components, such as metallic lines and metal silicide, etc.

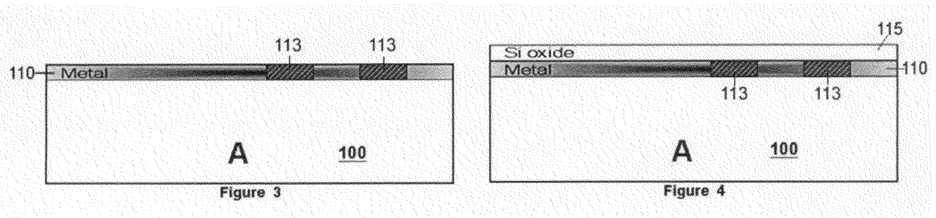

FIGS. 3 to 7 are a series of cross sectional views illustrating the processing steps to form a base structure with an electrically conductive layer beneath a single silicon layer ready to support electric circuit thereon. In FIG. 3, a conductive layer 110 is formed and patterned on top of a semiconductor wafer such as a silicon substrate 100. As described below, conductive layer 110 can be used to form bottom electrodes of memory elements. In some embodiments, conductive layer 110 is unpatterned at this stage of process. In certain other embodiments, conductive layer 110 can be patterned with no conductive material present in regions 113.

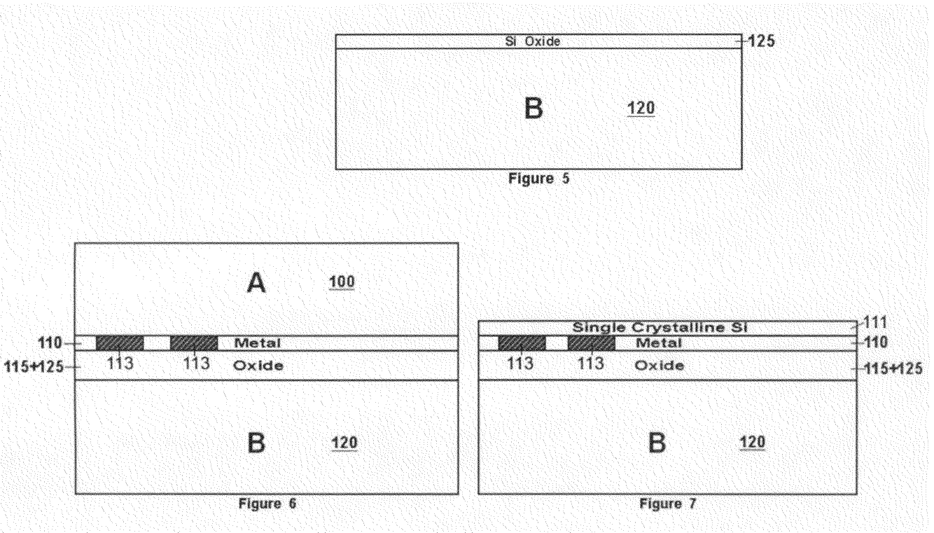

In FIG. 4, a silicon oxide layer 115 is deposited over conductive layer 110. In some embodiments, regions 113 now are filled with silicon oxide. In FIG. 5, a silicon oxide layer 125 is either grown or deposited on a second silicon wafer 120. In some embodiments, substrate 120 can be a single crystalline substrate such as silicon wafer. In other embodiments, substrate 120 can be a support substrate which can include glass, an oxide layer overlying a polysilicon layer, ceramic, or a dielectric layer.

In FIG. 6, the first silicon substrate 100 and the second silicon wafers or support substrate 120 are bonded together to form a bonded and combined oxide layer (115+125), using, for example, a conventional bonding method. As used herein, a combined dielectric layer or a composite dielectric layer refers to two separate dielectric layers bonded together, such as combined oxide layer 115 and 125. In some embodiments, the bonding strength between two oxide surfaces enables a strong device structure.

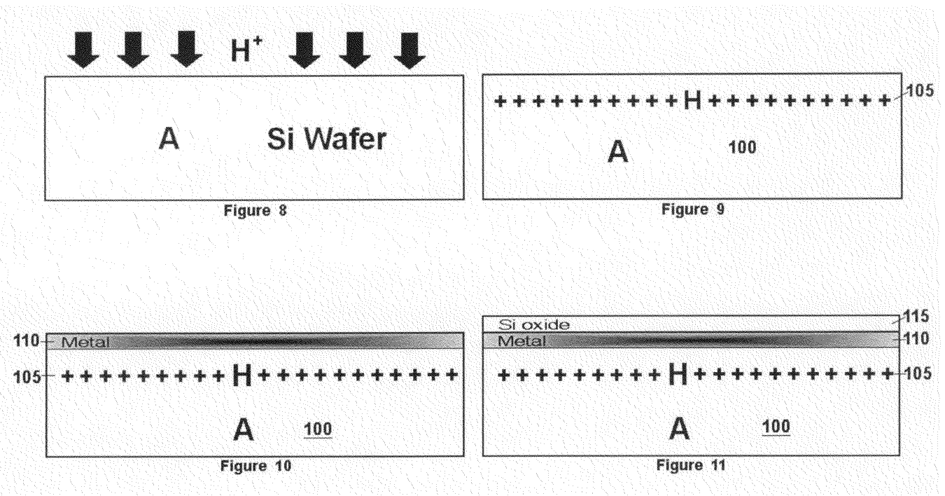

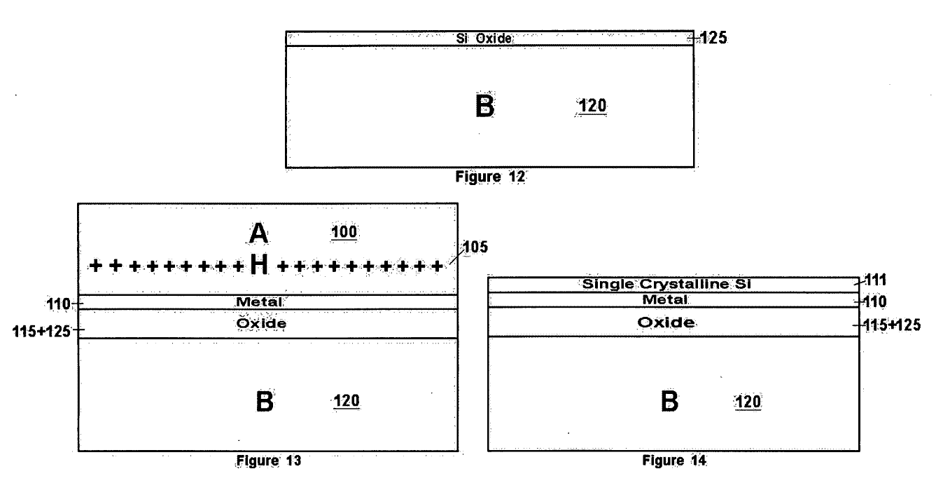

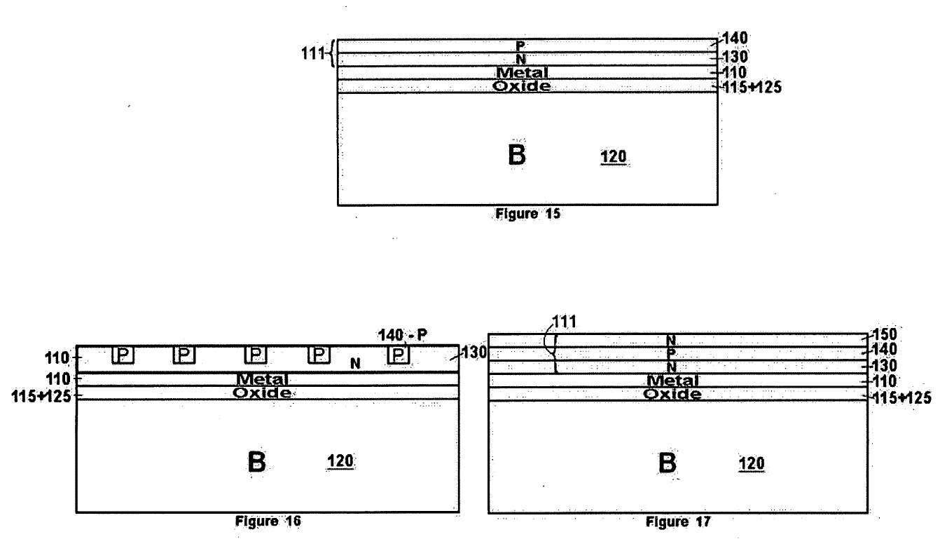

In FIG. 7, the top partial portion of the silicon wafer 100 is removed to leave a single crystal silicon layer 111 on top of the conductive layer 110. In the embodiments in which conductive layer 110 is patterned, some regions of the single crystalline silicon layer 111 above oxide regions 113 now form silicon-on-insulator (SOI) regions. These SOI regions can be isolated from the conductive layer 110, and various conventional SOI device and process techniques can be used to form desired circuits. Depending on the application, such circuits can include processors, logic circuits, analog circuits, and mixed signal circuits, etc.

In embodiments in which both substrate A and substrate B are silicon wafers, the memory arrays may be formed on substrate A or B, and the peripheral circuits may be formed on substrate A or B. The formation of the memory arrays can be before or after the wafer bonding process. The formation of the peripheral circuits can be before or after the wafer bonding process.

In some embodiments, the single crystal layer 111 is ready to form different types of memory or peripheral circuits with the metal layer 110 formed underneath to provide electrical connections. The peripheral circuits may be formed in the silicon layer 111 in the areas such as 113, that are away from the areas with the metal layer 110 underneath as silicon-on -Insulator (SOI) circuits. The conductive layer may be formed with Cu, W, TiN, TiW, Ni, refractory metal silicides such as Ti-Silicide, W-Silicide, Ni-Silicide, Co-Silicide, Polysilicon, and other conductive layers typically implemented in semiconductor industries for connecting circuits manufactured as the integrated circuits (IC).

FIGS. 8 to 14 are a series of cross sectional views to illustrate another sequence of processing steps to form a base structure with electrically conductive layer beneath a single silicon layers ready to support electric circuit thereon. In FIG. 8, hydrogen ions are implanted into a silicon wafer 100 to form a hydrogen-doped layer 105 of FIG. 9. In FIG. 10, a conductive layer 110 is deposited and, optionally, patterned, on top of the hydrogen implanted wafer 100. In FIG. 11, a silicon oxide layer 115 is either grown or deposited on top of the metal layer 110. In FIG. 12, a silicon oxide layer 125 is grown on a second silicon wafer or a glass substrate 120. In FIG. 13, the first and second wafers 120 and 100 are bonded together to form a bonded and combined oxide layer (115+125).

In FIG. 14, the top partial portion of the silicon wafer 100 is removed to leave a single crystal silicon layer 111 on top of the conductive layer 110. This single crystal silicon layer can be doped by ion implantation to form different doped layers, or can use epitaxial growth method to form different doped layers, or the combination of ion implantation and epitaxial growth. Similar to the discussion above in connection with FIGS. 3-7, the single crystal layer 111 is ready to form different types of memory arrays or peripheral circuits with the patterned metal layer 110 ready formed underneath to provide electrical connections. The peripheral circuits may be formed in the silicon layer 111 in the surface areas that are away from the areas with the metal layer 110 underneath. The conductive layer may be formed with Cu, W, TiN, Polysilicon, and conductive layers typically implemented in semiconductor industries for connecting circuits manufactured as the integrated circuits (IC). Similar to the discussion above, SOI regions above regions 113 can be utilized to formed desired circuitry.

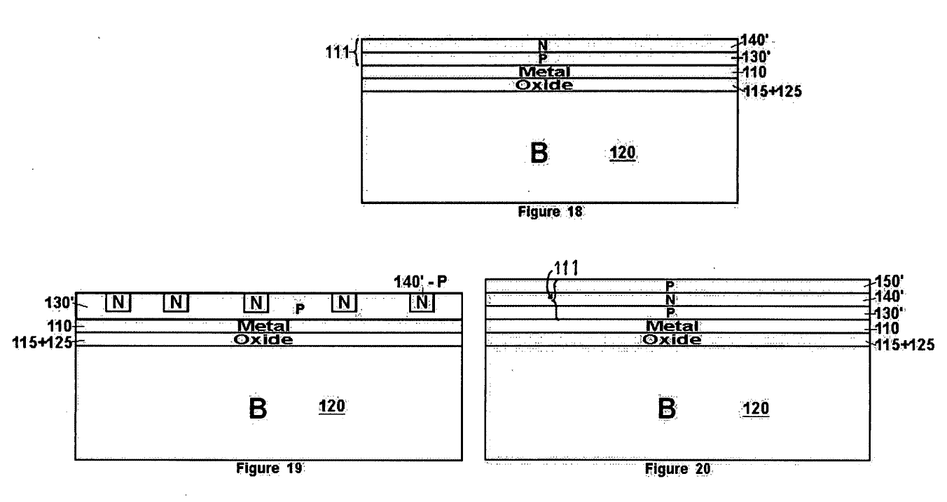

FIGS. 15 to 20 are a series of cross sectional views illustrating the fabrication steps for providing another base structure with single crystal layer on top of low resistivity conducting layer to form memory cells or other electric circuit thereon. FIG. 15 shows a cross sectional view of the top single crystal silicon layer (e.g., layer 111 of FIGS. 7 or 14) doped with an N-doped layer 130 and a P-doped layer 140. The cross sectional view in FIG. 16 shows that selective regions in the N-doped layer 130 are formed as P-doped regions 140-P by applying a P-dopant mask (not shown) followed by ion implantation. In FIG. 17, the top single crystal silicon layer (e.g., layer 111 of FIG. 7 or 14) is doped as a N-doped layer 130, a P-doped layer 140, and a second N-doped layer 150.

In FIG. 18, the top single crystal silicon layer 111 is doped with a P-layer 130′ and an N-doped layer 140′. In FIG. 19, selective regions in the P-doped layer 130′ are formed as N-doped regions 140′-N by applying an N-dopant mask (not shown) followed by ion implantation. In FIG. 20, the top single crystal silicon layer 111 is doped as a P-doped layer 130′, an N-doped layer 140′, and a second P-doped layer 150′.

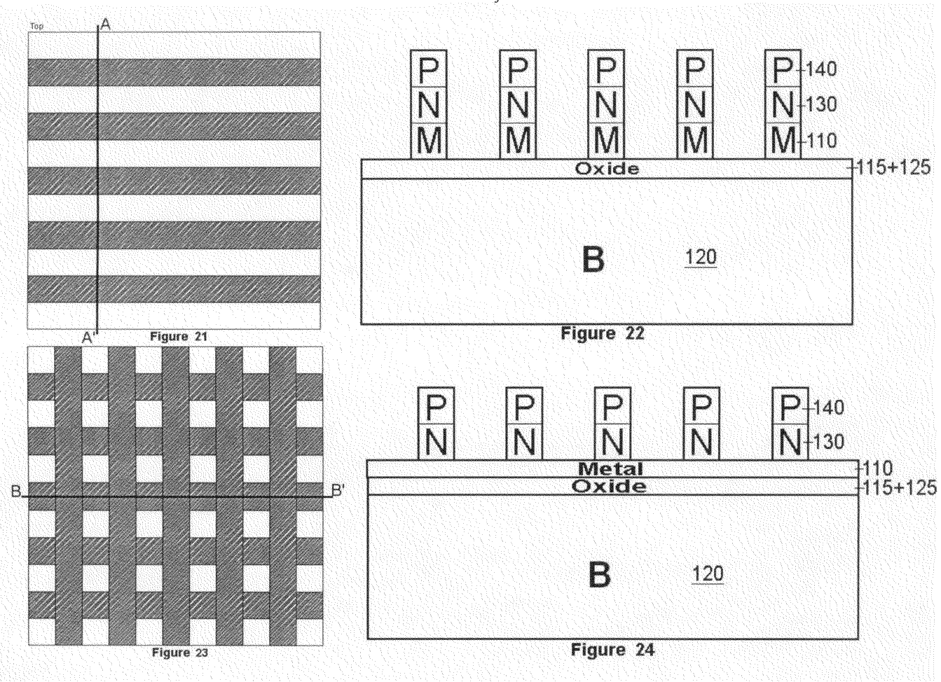

FIGS. 21-24 are respectively a top views and cross sectional views of a based structure and a method for forming such structure for supporting and manufacturing PCM memory cells thereon. FIG. 21 is a top view of a mask to form the structure in FIG. 22 and FIG. 22 is a side cross sectional view along the line A-A′ of FIG. 21 of the base structure to form the diodes and metal lines supporting the PCM cells functions. The base structure is formed by applying a mask, as shown in the heavy lined areas, followed by carrying out a process to etch and pattern the P-layer 140, the N-doped layer 130, and the metal layer 110.

FIGS. 23 and 24 are respectively a top view and cross sectional view of another step in manufacturing PCM memory cells. FIG. 23 is a top view of two masks used to form the structure in FIG. 24. The heavy horizontal lined areas corresponding to the mask shown in FIG. 21, and the light vertical lined areas correspond to the second mask used to form islands of PN diodes. FIG. 24 is a side cross sectional view along the line B-B′ of FIG. 23 of the base structure to form the diodes and metal lines supporting PCM cells functions. The base structure is formed by applying a mask, as shown in FIG. 23 of the light vertical lined area, followed by carrying out a process to etch and pattern the P-layer 140 and the N-doped layer 130. In an embodiment, the horizontal and the vertical masks have patterns that are perpendicular to one another, and the resulting base cell structures are rectangular in shape, having a series of diodes as switching devices coupled to a conductive line.

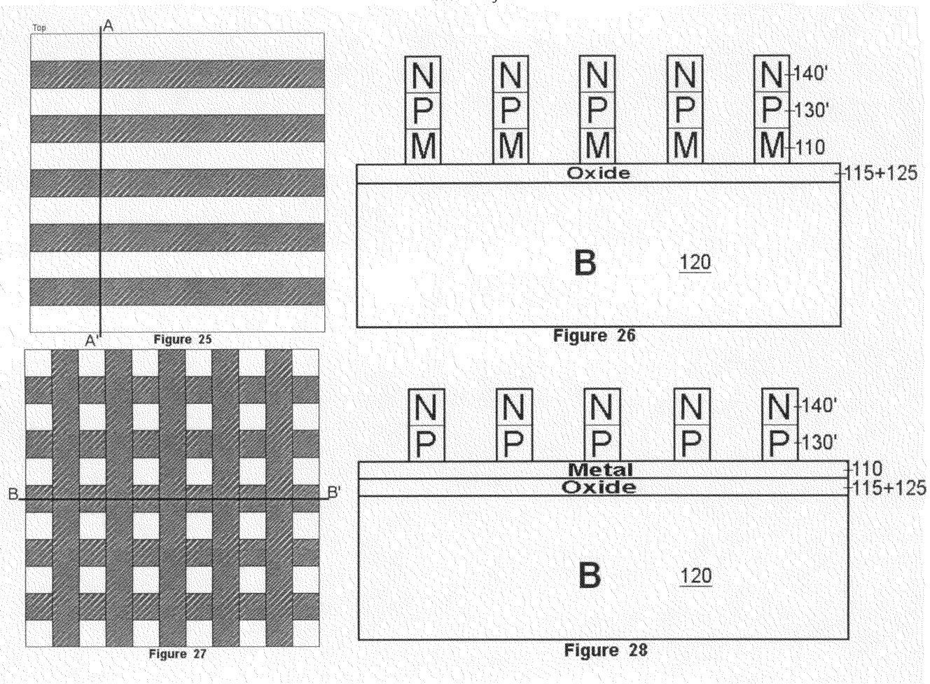

FIGS. 25 to 28 are similar to FIGS. 21 to 24 except that the doping polarities of the top layers are reversed.

Thus, according to some embodiments of the present invention, a semiconductor substrate has a top surface region including a single crystal silicon layer with a predefined thickness disposed immediately above a metal layer on top of a combined dielectric layer, which can have a first dielectric layer, a bonding interface; and a second dielectric layer. The first and the second dielectric layers are bonded together at the bonding interface. In a specific embodiment, the single crystal silicon layer further includes one or more diodes. In some other embodiments, the single crystal silicon layer further includes one or more bipolar transistors. In yet other embodiments, the single crystal layer further includes peripheral circuit formed therein configured to support functions of a phase change memory (PCM) device. In alternative embodiments, the single crystal layer further includes peripheral circuit formed therein configured to support functions of a magnetic random access memory (MRAM) device. In some embodiments, the metal layer further includes patterned metal lines configured to function as a signal and control conductive lines for a PCM device. In some embodiments, the metal layer further includes patterned metal lines configured to function as a signal and control conductive lines for a MRAM device. In some embodiment, the semiconductor substrate also includes a single crystalline silicon substrate underlying the combined dielectric layer. In other embodiments, the semiconductor substrate also has a support substrate underlying the combined dielectric layer, the support substrate comprising glass, an oxide layer overlying a polysilicon layer, ceramic, or a dielectric layer.

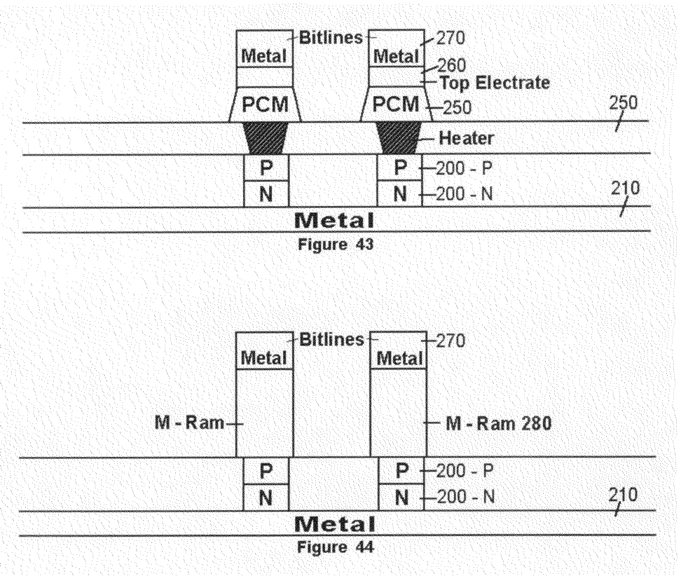

In some embodiments, the base cell structures of FIGS. 22, 24, 26, and 28 can be used as a basis over which PCM memory material and top conductive layers are built. An example of PCM cell structure is described below in connection with FIG. 43. In other embodiments, other layers in a PCM memory can be formed over base layers such as those illustrated in FIGS. 15-20. Then the two step etching method using two mask layers, as illustrated in FIGS. 21-28, can be used to form memory cell stacks including top electrode, PCM material such as GST, bottom electrode, heater, etc.

According to some embodiments of the invention, a memory device includes a composite dielectric layer overlying a substrate. The composite dielectric layer has a first dielectric layer, a bonding interface, and a second dielectric layer, and the first and the second dielectric layers are bonded together at the bonding interface. The memory device also has a first plurality of conductive lines overlying the combined dielectric layer. One or more semiconductor switching devices are formed in a single-crystalline semiconductor layer overlying and coupled with one of the first plurality of conductive lines. The memory device has one or more two-terminal memory elements, each of which overlies and is being coupled to a corresponding one of the single-crystalline switching devices. A second plurality of conductive lines overlies the memory elements. Each of the memory elements is coupled to one of the first plurality of conductive lines and one of the second plurality of conductive lines.

In a specific embodiment, each of the two-terminal memory elements comprises a phase change memory (PCM) material. An example of such a memory device is described below in connection with FIGS. 43 and 44. In another embodiment, each of the two-terminal memory elements comprises an MRAM material. In yet another embodiment, each of the two-terminal memory elements comprises a memrister material. In some embodiments, each of the two-terminal memory elements has a memory material whose conductivity property can be set by an applied voltage and the memory material retains the conductivity property after the applied voltage is removed. In some embodiments, the one or more semiconductor switching devices comprise diodes. In some other embodiments, the one or more semiconductor switching devices comprise transistors. In certain embodiments, the memory device also includes semiconductor periphery devices underlying the combined dielectric layer, the periphery devices configured to support operation of the memory device.

In some embodiments of the memory device, each of the one or more semiconductor switching devices is in direct contact with one of the first plurality of conductive lines. In certain embodiments, the single-crystalline semiconductor layer further includes peripheral circuits formed therein and configured to support functions of a phase change memory (PCM) device. In other embodiments, the memory device also includes peripheral circuits overlying the composite dielectric layer and configured to support functions of a phase change memory (PCM) device. In a specific embodiment, the substrate comprises a single crystalline semiconductor substrate. In another embodiment, the substrate comprises a support substrate.

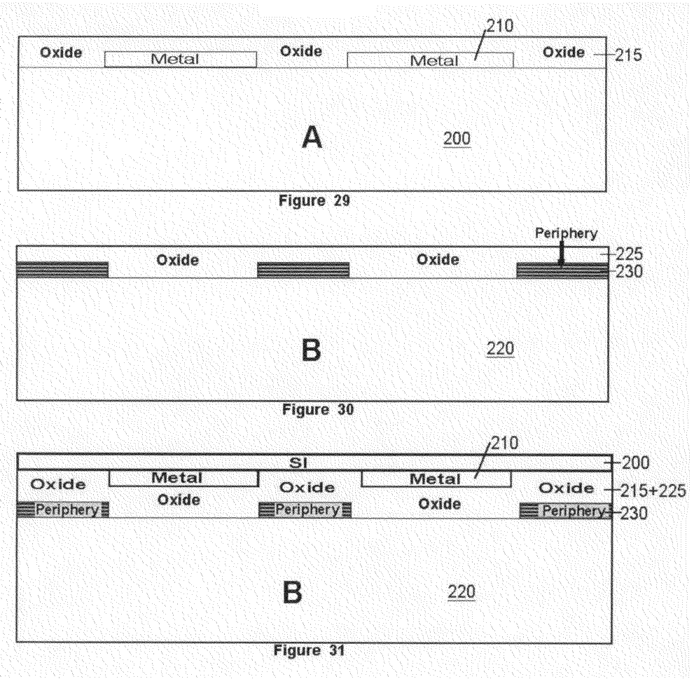

According to another embodiment of the present invention, a method for forming a memory device includes forming a single-crystalline semiconductor layer overlying and in direct contact with a metal layer, and forming two or more doped layers in the single-crystalline semiconductor layer. The method includes forming a layer of memory material overlying the single-crystalline semiconductor layer, wherein the memory material's conductivity property can be set by an applied voltage and the memory material retains the conductivity property after the applied voltage is removed. The method also includes forming a layer of conductive material overlying the layer of memory material. Some embodiments of the method have been described above in connection with FIGS. 3-28. Other embodiments are described below in connection with FIGS. 29-44.

In a specific embodiment, the method also includes patterning the layer of memory material, the doped layers, and the metal layer using a first masking layer having a first pattern of stripes, and patterning the layer of memory material and the doped layers using a second masking layer having a second pattern of stripes, while leaving the metal layer substantially unchanged. A memory element is formed at each intersection between the first pattern of stripes and the second pattern of stripes, and the memory element includes a region of the memory material and a switching device formed by the patterned doped layers. In an embodiment, the single-crystalline semiconductor switching devices include diodes. In another embodiment, the single-crystalline semiconductor switching devices includes transistors.

In some embodiments of the method, forming the single-crystalline semiconductor layer includes depositing the metal layer on a top surface of a first semiconductor substrate including single crystal silicon, followed by forming a first dielectric layer on top of said metal layer. A second dielectric layer is formed on a top surface of a second semiconductor substrate. Then, the first and the second dielectric layers are bonded to form a composite dielectric layer. A portion of the first semiconductor substrate is removed to form a single-crystalline semiconductor layer with a predefined thickness that is in direct contact with the metal layer. In some embodiments, the method also includes forming semiconductor periphery devices in and over the second semiconductor substrate.

In alternative embodiments of the method, forming the single-crystalline semiconductor layer overlying and in direct contact with the metal layer further includes depositing the metal layer on a top surface of a first semiconductor substrate including single crystal silicon, followed by forming a first dielectric layer on top of said metal layer. Then the first dielectric layer is bonded to a support substrate. A portion of the first semiconductor substrate is subsequently removed to form a single-crystalline silicon layer with a predefined thickness that is in direct contact with the metal layer.

In some embodiments of the method the memory material comprises PCM material. In other embodiments, the memory material includes MRAM material. In still other embodiments, the memory material includes memrister material. In certain embodiments, the memory material's conductivity property can be set by an applied voltage and the memory material retains the conductive property after the applied voltage is removed.

FIGS. 29 to 31 are a series of cross sectional views for showing the processing steps to form a based structure provided to support and form a phase change memory (PCM) thereon. In FIG. 29, a first semiconductor wafer 200 is deposited with a metal layer and the metal layer is patterned as metal conducting lines 210. Then, the top surface is covered with an oxide layer 215. In FIG. 30, a second wafer 220 is formed with peripheral circuit 230 for the PCM device such as memory controller, decoders, input and output circuitry. Then, the wafer is covered with an oxide layer 225. In FIG. 31, the first and second wafers are bonded together with an oxide glue to form a combined oxide layer (215+225). Then the top portion of the silicon wafer 200 is removed. A top single crystal silicon layer 200 is available on the top to form the diodes or transistors needed to form the phase change memory cells thereon with good contact to the metal conducting lines 210 immediately below the single crystal silicon layer 200.

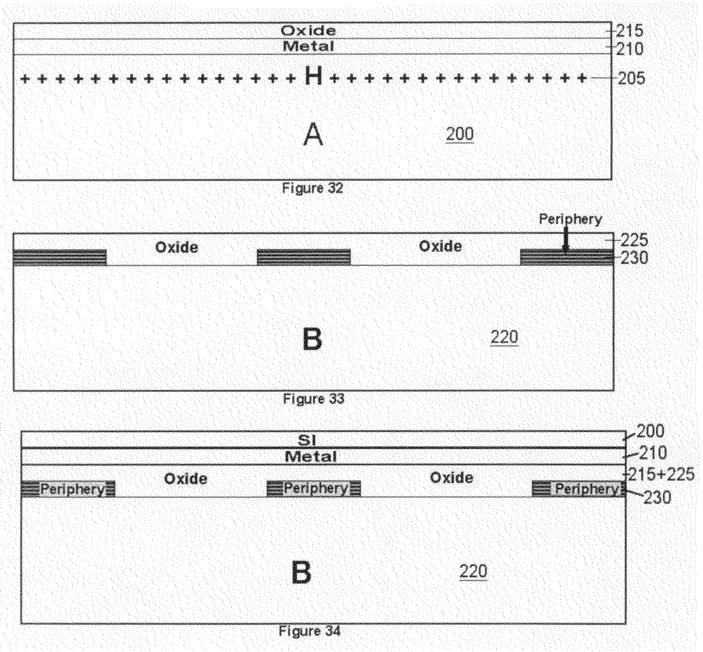

FIGS. 32 to 34 are a series of cross sectional views for showing the processing steps to form a based structure provided to support and form a phase change memory (PCM) thereon. In FIG. 32, a first semiconductor wafer 200 implanted with hydrogen ions to form a hydrogen-doped layer 205. Then a metal layer is deposited as a metal layer 210 on the top surface of the silicon wafer 200. Then, the top surface is covered with an oxide layer 215. In FIG. 33, a second wafer 220 is formed with peripheral circuit 230 for the PCM device such as controller, decoders, input and output circuitry. Then, the wafer is covered with an oxide layer 225. In FIG. 34, the first and second wafers are bonded together with an oxide glue to form a combined oxide layer (215+225). Then the top portion of the silicon wafer 200 is removed. A top single crystal silicon layer 200 is available on the top to form the diodes or transistors needed to form the phase change memory cells thereon with good contact to the metal layer 210 immediately below the single crystal silicon layer 200.

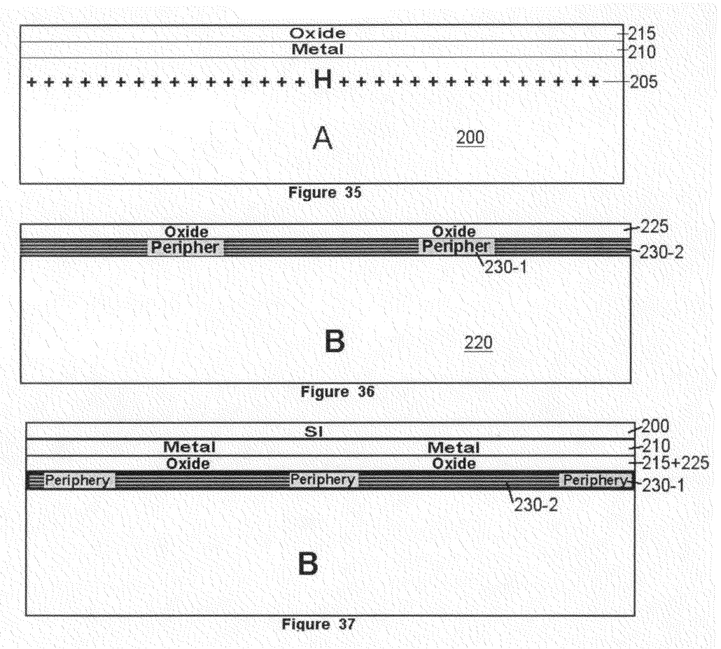

FIGS. 35 to 37 are a series of cross sectional views for showing the processing steps to form a based structure provided to support and form a phase change memory (PCM) thereon. In FIG. 35, a first semiconductor wafer 200 implanted with hydrogen ions to form a hydrogen-doped layer 205. Then a metal layer is deposited as a metal layer 210 on top of the silicon wafer 200. Then, the top surface is covered with an oxide layer 215. In FIG. 36, a second wafer 220 is formed with peripheral circuit 230-1 and connecting wires 230-2 for the PCM device such as controller, decoders, input and output circuit. 230-1 connected to the connecting wires 230-2. Then, the wafer is covered with an oxide layer 225. In FIG. 37, the first and second wafers are bonded together with an oxide glue to form a combined oxide layer (215+225). A top portion of the silicon wafer 200 is partially removed. A top single crystal silicon layer 200 with controlled thickness IS kept on the top to form the diodes or transistors needed to form the phase change memory cells or other electronic devices thereon with low resistivity contact to the metal conducting lines 210 immediately below the single crystal silicon layer 200.

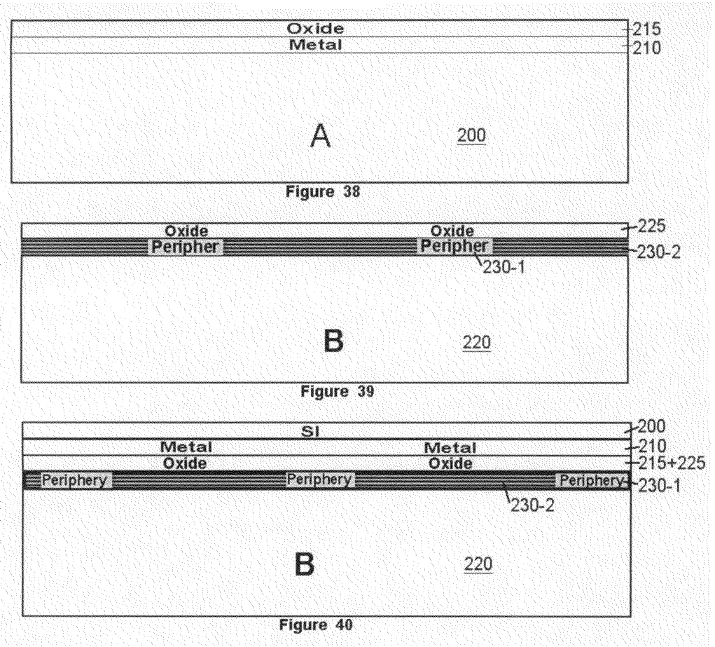

FIGS. 38 to 40 are a series of cross sectional views for showing the processing steps to form a based structure provided to support and form a phase change memory (PCM) thereon. In FIG. 38, a metal layer is deposited on top of the silicon wafer 200. Then, the top surface is covered with an oxide layer 215. In FIG. 39, a second wafer 220 is formed with peripheral circuit 230-1 and connecting wires 230-2 for the PCM device such as controller, decoders, input and output circuitry. 230-1 connected to the connecting wires 230-2. Then, the wafer is covered with an oxide layer 225. In FIG. 40, the first and second wafers are bonded together with an oxide glue to form a combined oxide layer (215+225). Then the top portion of the silicon wafer 200 is partially removed. A top single crystal silicon layer 200 is available on the top to form the diodes or transistors needed to form the phase change memory cells thereon with good contact to the metal layer 210 formed immediately the single crystal silicon layer 200.

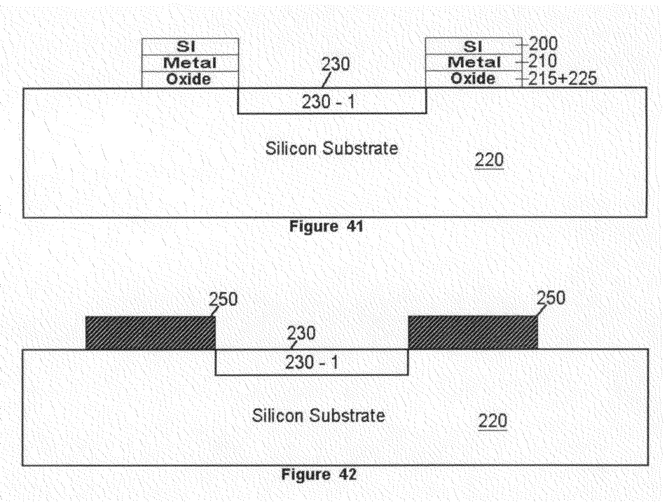

FIG. 41 shows the base structure etched with patterned oxide layer (215+255) supporting a electrode layer 210 with a single crystal silicon layer 200 to form the diodes or transistors needed to form the PCM memory cells thereon with peripheral circuit 230-1 formed on the adjacent areas 230 of the top surface of the silicon wafer 220. FIG. 42 is a cross sectional view of the PCM memory cells 250 supported on the silicon wafer 220 formed with peripheral circuits 230-1 adjacent to the memory cells 250. The peripheral circuits can be formed before, during or after the manufacturing processes of the PCM memory cells on the base-structure to form the PCM memory cells thereon.

Referring to FIG. 43 for the detailed structure of a phase change memory (PCM) 250 supported on a base structure manufactured according to the above described processes. The base structure includes a metal layer 210 as shown in FIG. 41 with a single crystal silicon layer formed with a N-layer 210-N and P-layer 210-P to function as diodes for supporting a heater 255 thereon for applying heat to the PCM 250. The PCM device further includes a top electrodes 260 connected to metal lines 270 to function as bit lines on the top of the PCM device. FIG. 44 is another embodiment of this invention with the base structure supports a magnetic random access memory (MRAM) 280 thereon connected with bitlines on the top surface for accessing each of the MRAM cells. In other embodiments, the methods and structures provided by the invention can be applied memory devices including, e.g., memrister memory structures.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A memory device, comprising:
a composite dielectric layer overlying a substrate, the composite dielectric layer including a first dielectric layer, a bonding interface, and a second dielectric layer, wherein the first and the second dielectric layers are bonded together at the bonding interface;
a first plurality of conductive lines overlying the combined dielectric layer;
one or more semiconductor switching devices formed in a single-crystalline semiconductor layer overlying and coupled with one of the first plurality of conductive lines;
one or more two-terminal memory elements, each two-terminal memory element overlying and being coupled to a corresponding one of the single-crystalline switching devices; and
a second plurality of conductive lines overlying the memory elements,
wherein each of the memory elements is coupled to one of the first plurality of conductive lines and one of the second plurality of conductive lines.

2. The memory device of claim 1, wherein each of the two-terminal memory elements comprises a phase change memory (PCM) material.

3. The memory device of claim 1, wherein each of the two-terminal memory elements comprises an MRAM material.

4. The memory device of claim 1, wherein each of the two-terminal memory elements comprises a memrister material.

5. The memory device of claim 1, wherein each of the two-terminal memory elements comprises a memory material whose conductivity property can be set by an applied voltage and the memory material retains the conductivity property after the applied voltage is removed.

6. The memory device of claim 1, wherein the one or more semiconductor switching devices comprise diodes.

7. The memory device of claim 1, wherein the one or more semiconductor switching devices comprise transistors.

8. The memory device of claim 1 further comprising semiconductor periphery devices underlying the combined dielectric layer, the periphery devices configured to support operation of the memory device.

9. The memory device of claim 1, wherein each of the one or more semiconductor switching devices is in direct contact with one of the first plurality of conductive lines.

10. The memory device of claim 1 wherein the single-crystalline semiconductor layer further includes peripheral circuits formed therein and configured to support functions of a phase change memory (PCM) device.

11. The memory device of claim 1 further comprising peripheral circuits overlying the composite dielectric layer and configured to support functions of a phase change memory (PCM) device.

12. The memory device of claim 1 wherein the substrate comprises a single crystalline semiconductor substrate.

13. The memory device of claim 1 wherein the substrate comprises a support substrate.

14. A method for forming a memory device, comprising:
forming a single-crystalline semiconductor layer overlying and in direct contact with a metal layer;
forming two or more doped layers in the single-crystalline semiconductor layer;
forming a layer of memory material overlying the single-crystalline semiconductor layer, wherein the memory material's conductivity property can be set by an applied voltage and the memory material retains the conductivity property after the applied voltage is removed; and
forming a layer of conductive material overlying the layer of memory material.

15. The method of claim 14 further comprising:
patterning the layer of memory material, the doped layers, and the metal layer using a first masking layer having a first pattern of stripes; and
patterning the layer of memory material and the doped layers using a second masking layer having a second pattern of stripes, while leaving the metal layer substantially unchanged,
whereby a memory element is formed at each intersection between the first pattern of stripes and the second pattern of stripes, the memory element comprising a region of the memory material and a switching device formed by the patterned doped layers.

16. The method of claim 15, wherein the single-crystalline semiconductor switching devices comprise diodes.

17. The method of claim 15, wherein the single-crystalline semiconductor switching devices comprise transistors.

18. The method of claim 14 wherein forming the single-crystalline semiconductor layer overlying and in direct contact with the metal layer further comprises:
depositing the metal layer on a top surface of a first semiconductor substrate including single crystal silicon, followed by forming a first dielectric layer on top of said metal layer;
forming a second dielectric layer on a top surface of a second semiconductor substrate;
bonding said first and said second dielectric layers to form a composite dielectric layer; and
removing a portion of said first semiconductor substrate to form a single-crystalline semiconductor layer with a predefined thickness that is in direct contact with the metal layer.

19. The method of claim 18 further comprising forming semiconductor periphery devices in and over the second semiconductor substrate.

20. The method of claim 14 wherein forming the single-crystalline semiconductor layer overlying and in direct contact with the metal layer further comprises:
depositing the metal layer on a top surface of a first semiconductor substrate including single crystal silicon, followed by forming a first dielectric layer on top of said metal layer;
bonding said first dielectric layer to a support substrate; and
removing a portion of said first semiconductor substrate to form a single-crystalline silicon layer with a predefined thickness that is in direct contact with the metal layer.

21. The method of claim 14, wherein the memory material comprises PCM material.

22. The method of claim 14, wherein the memory material comprises MRAM material.

23. The method of claim 14, wherein the memory material comprises memrister material.

24. The method of claim 14, wherein the memory material's conductivity property can be set by an applied voltage and the memory material retains the conductivity property after the applied voltage is removed.

25. A semiconductor substrate comprising a top surface region including a single crystal silicon layer with a predefined thickness disposed immediately above a metal layer on top of a combined dielectric layer, the combined dielectric layer having a first dielectric layer, a bonding interface; and a second dielectric layer, wherein the first and the second dielectric layers are bonded together at the bonding interface.

26. The semiconductor substrate of claim 25 wherein the single crystal silicon layer further includes one or more diodes.

27. The semiconductor substrate of claim 25 wherein the single crystal silicon layer further includes one or more bipolar transistors.

28. The semiconductor substrate of claim 25 wherein the single crystal layer further includes peripheral circuit formed therein configured to support functions of a phase change memory (PCM) device.

29. The semiconductor substrate of claim 25 wherein the single crystal layer further includes peripheral circuit formed therein configured to support functions of a magnetic random access memory (MRAM) device.

30. The semiconductor substrate of claim 25 wherein the metal layer further includes patterned metal lines configured to function as a signal and control conductive lines for a PCM device.

31. The semiconductor substrate of claim 25 wherein the metal layer further includes patterned metal lines configured to function as a signal and control conductive lines for a MRAM device.

32. The semiconductor substrate of claim 25 further comprising a single crystalline silicon substrate underlying the combined dielectric layer.

33. The semiconductor substrate of claim 25 further comprising a support substrate underlying the combined dielectric layer, the support substrate comprising glass, an oxide layer overlying a polysilicon layer, ceramic, or a dielectric layer.

34. A method for manufacturing a base structure to support an integrated circuit (IC) thereon, comprising:
depositing a metal layer on a top surface of a first semiconductor substrate including a single crystal silicon, followed by forming a first oxide layer on top of said metal layer; and
forming a second oxide layer on a top surface of a second substrate followed by bonding said first and second oxide layers to form a combined oxide layer and removing a portion of said first semiconductor substrate to form a single crystal silicon layer with a predefined thickness and having the metal layer immediately thereunder.

35. The method of claim 34 wherein depositing the metal layer on the top surface of the first semiconductor substrate further includes implanting hydrogen ions into the first semiconductor substrate composed of the single crystal silicon before depositing the metal layer on the top surface.

36. The method of claim 34 further comprising implanting the single crystal silicon layer with P-dopant ions and N-dopant ions to form diodes therein.

37. The method of claim 34 further comprising implanting the single crystal silicon layer with P-dopant ions, N-dopant ions, and P-dopant ions to form PNP bipolar transistors therein.

38. The method of claim 34 further comprising implanting the single crystal silicon layer with N-dopant ions, P-dopant ions, and N-dopant ions to form NPN bipolar transistors therein.

39. The method of claim 34 wherein the second substrate is a single crystalline semiconductor substrate.

40. The method of claim 34 wherein the second substrate comprises a support substrate that includes one or more of glass, an oxide layer overlying a polysilicon layer, ceramic, or a dielectric layer.
